(19) United States
(12) Patent Application Publication
(10) Pub. No.: US 2025/0183154 A1
(43) Pub. Date: Jun. 5, 2025

(54) PHOTOELECTRIC CONVERSION APPARATUS

(71) Applicant: CANON KABUSHIKI KAISHA, Tokyo (JP)

(72) Inventor: TAKAFUMI MIKI, Kanagawa (JP)

(73) Assignee: CANON KABUSHIKI KAISHA, Tokyo (JP)

(21) Appl. No.: 18/952,155

(22) Filed: Nov. 19, 2024

(30) Foreign Application Priority Data
Nov. 30, 2023 (JP) 2023-202722

(51) Int. Cl. H01L 23/522; H01L 27/146

(52) U.S. Cl. CPC H01L 23/5225; H10F 39/811

(57) ABSTRACT

An apparatus includes a plurality of pixels each including a photoelectric conversion unit; a floating diffusion unit; an amplifying transistor that has a gate; and a selection transistor, a shield wiring disposed to cover at least a part of the gate in a planar view, a first diffusion region, a second diffusion region, at least one first contact, and at least one second contact, wherein the gate, the first diffusion region, and the second diffusion region are adjacently disposed on a straight line in a first direction, and wherein, in a second direction perpendicularly intersecting with the first direction, a sum of widths of the at least one first contact is longer than a sum of widths of the at least one second contact.

### BACKGROUND

### Technical Field

The aspect of the embodiments relates to a photoelectric conversion apparatus.

### Description of the Related Art

In recent years, complementary metal oxide semiconductor (CMOS) image sensors suitable for high-speed reading have been widely used for digital still cameras, digital video cameras, and other imaging apparatuses. For example, Japanese Patent Application Laid-Open No. 2023-84462 proposes a crosstalk preventive CMOS image sensor in which a shield wiring, to which the output potential of an amplifying transistor is supplied, is disposed between a wiring connected with a floating diffusion and a transfer control line. In the CMOS image sensor discussed in Japanese Patent Application Laid-Open No. 2023-84462, the shield wiring, to which the output potential of the amplifying transistor is supplied, is disposed between the wiring connected with the floating diffusion and the transfer control line.

However, depending on the layout, crosstalk may be insufficiently controlled with the CMOS image sensor with the above-described technique.

### SUMMARY

According to an aspect of the embodiments, a plurality of pixels each including a photoelectric conversion unit, a floating diffusion unit, an amplifying transistor that has a gate and is configured to amplify a signal based on the floating diffusion unit and output the signal as a pixel signal, and a selection transistor configured to control output of the amplified pixel signal, a shield wiring disposed to cover at least a part of the gate in a planar view viewed from a direction perpendicularly intersecting with a surface where the plurality of pixels is disposed, a first diffusion region configured to serve as a source or drain of the amplifying transistor, a second diffusion region configured to serve as a source or drain of the selection transistor, at least one first contact connected to the first diffusion region, and at least one second contact connected to the second diffusion region, wherein the gate, the first diffusion region, and the second diffusion region are adjacently disposed on a straight line in a first direction, and wherein, in a second direction perpendicularly intersecting with the first direction, a sum of widths of the at least one first contact is longer than a sum of widths of the at least one second contact.

According to another aspect of the embodiments, an apparatus includes a plurality of pixels each including a photoelectric conversion unit, a floating diffusion unit, an amplifying transistor that has a gate and is configured to amplify a signal based on the floating diffusion unit and output the signal as a pixel signal, a selection transistor configured to control output of the pixel signal amplified by the amplifying transistor, and a wiring mainly made of copper, a first diffusion region configured to serve as a source or drain of the amplifying transistor, a second diffusion region configured to serve as the source or drain of the selection transistor, at least one first contact connected to the first diffusion region and the wiring, and at least one second contact connected to the second diffusion region, wherein the gate, the first diffusion region, and the second diffusion region are adjacently disposed on a straight line in a first direction, and wherein, in a second direction perpendicularly intersecting with the first direction, a sum of widths of the at least one first contact is longer than a sum of widths of the at least one second contact.

Further features of the disclosure will become apparent from the following description of exemplary embodiments with reference to the attached drawings.

### BRIEF DESCRIPTION OF THE DRAWINGS

FIG. 1 is a block diagram illustrating a photoelectric conversion apparatus according to a first exemplary embodiment.

FIG. 2 is a circuit diagram illustrating pixels according to the first exemplary embodiment.

FIG. 3 is a timing chart of each control line according to the first exemplary embodiment.

FIGS. 4A to 4C are plan views illustrating pixels according to the first exemplary embodiment.

FIG. 5 is a cross-sectional view illustrating a pixel according to the first exemplary embodiment.

FIGS. 6A to 6C are plan views illustrating pixels according to a second exemplary embodiment.

FIGS. 7A to 7C are plan views illustrating pixels according to a third exemplary embodiment.

FIG. 8 is a circuit diagram illustrating pixels according to a fourth exemplary embodiment.

FIGS. 9A to 9C are plan views illustrating pixels according to the fourth exemplary embodiment.

FIG. 10 is a functional block diagram illustrating a photoelectric conversion system according to a fifth exemplary embodiment.

FIGS. 11A and 11B are functional block diagrams illustrating a photoelectric conversion system according to a sixth exemplary embodiment.

FIG. 12 is a functional block diagram illustrating a photoelectric conversion system according to a seventh exemplary embodiment.

FIG. 13 is a functional block diagram illustrating a photoelectric conversion system according to an eighth exemplary embodiment.

FIG. 14 is a functional block diagram illustrating a photoelectric conversion system according to a ninth exemplary embodiment.

FIG. 15A and 15B are functional block diagrams illustrating a photoelectric conversion system according to a tenth exemplary embodiment.

FIG. 16 is a cross-sectional view illustrating an internal configuration of a document reading apparatus according to an eleventh exemplary embodiment.

FIG. 17 is a block diagram illustrating a configuration of a control unit of the document reading apparatus according to the eleventh exemplary embodiment.

FIG. 18 is a flowchart illustrating control by a central processing unit (CPU) according to the eleventh exemplary embodiment.

### DESCRIPTION OF THE EMBODIMENTS

Hereinafter, each exemplary embodiment will be described with reference to the drawings. The exemplary embodiments described below are intended to embody the technical idea of the disclosure and how to carry it into effect and should be considered to not limit the disclosure. The size and positional relationship of members illustrated in the drawings may be exaggerated for clarity of description. In the following description, the same components are denoted by the same reference numerals, and the redundant description may be omitted. In the present specification, components having the same configuration are denoted by reference numerals with “−” and a figure in such a manner as −1, −2, and −3 added to the ends thereof, and description thereof may be omitted.

In the following description, terms indicating specific directions and positions (for example, “upper”, “lower”, “right”, “left”, and other terms including these terms) are used as necessary, and these terms are used to facilitate understanding of the embodiments with reference to the drawings, and the technical scope of the disclosure is not limited by the meanings of these terms.

According to the present specification, a plane refers to a surface viewed from a direction perpendicular to the light incidence surface of a semiconductor layer. A cross-section refers to a surface in a direction perpendicular to the light incidence surface of the semiconductor layer. If the light incidence surface of the semiconductor layer is a coarse surface when macroscopically viewed, a plane and a cross-section are defined with reference to the light incidence surface of the semiconductor layer when macroscopically viewed. A planar view refers to viewing the above-described plane. For example, a planar view refers to viewing from a direction perpendicularly intersecting with a surface where a plurality of pixels is arranged.

Exemplary embodiments will be described below centering on an imaging apparatus as an example of a photoelectric conversion apparatus. The exemplary embodiments are not limited to imaging apparatuses but also applicable to other examples of photoelectric conversion apparatuses. Examples of photoelectric conversion apparatuses include a distance measurement apparatus (an apparatus for measuring distance using focal point detection and Time Of Flight [TOF]), and a photometric apparatus (an apparatus for measuring the incident light quantity).

Conductivity types of transistors according to the exemplary embodiments (described below) are to be considered as illustrative. The disclosure is not limited to the conductivity types according to the exemplary embodiments. The conductivity types according to the exemplary embodiments can be suitably changed. With this change, the potentials of the gate, source, and drain of a transistor are to be suitably changed.

For example, in a case where the conductivity type of a transistor that is operated as a switch is changed, the low and the high levels of the potential to be supplied to the gate may be reversed with respect to the description of the exemplary embodiments. The conductivity type of the semiconductor region according to the exemplary embodiments (described below) are to be considered as illustrative but not limited to the conductivity type according to the exemplary embodiments. The conductivity type according to the exemplary embodiments can be suitably changed. With this change, the potential of the semiconductor region is suitably changed.

The following exemplary embodiments include descriptions of a connection between circuit elements. In such a case, unless otherwise noted, it is considered that target elements are connected to each other, even in a case where another element exists between the target elements. For example, an element A is connected to one node of a capacitive element C having a plurality of nodes, and an element B is connected to the other node of the capacitive element C. Even in such a case, it is considered that the elements A are B are connected to each other unless otherwise noted.

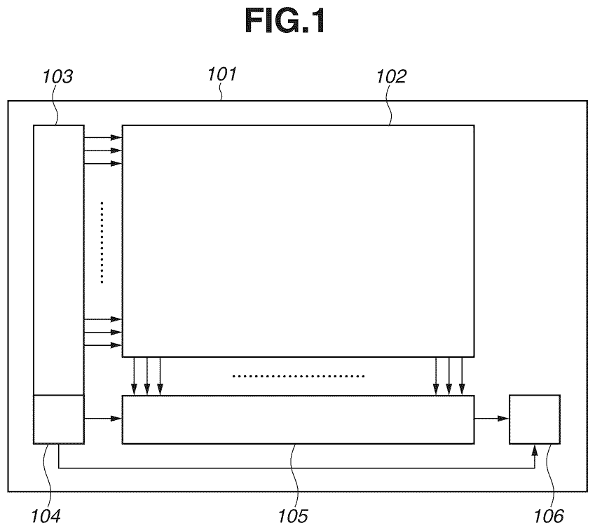

FIG. 1 is a schematic block diagram illustrating a photoelectric conversion apparatus according to a first exemplary embodiment. The photoelectric conversion apparatus 101 includes a photoelectric conversion region 102 where a plurality of pixels is arranged in a matrix form, a vertical scanning circuit 103 for driving each unit in the pixels, a power supply unit 104, a horizontal scanning circuit 105 for reading electrical signals of the pixels, and an output unit 106 for outputting electrical signals of the pixels. The plurality of pixels is arranged in a plurality of rows and a plurality of columns. With the photoelectric conversion apparatus 101, the light quantity on the photoelectric conversion region 102 is output as a two-dimensional electrical signal.

In the photoelectric conversion apparatus 101, the photoelectric conversion region 102 may be disposed in a first semiconductor layer, and the vertical scanning circuit 103, the power supply unit 104, the horizontal scanning circuit 105, and the output unit 106 may be disposed in a second semiconductor layer. The first and the second semiconductor layers may be stacked.

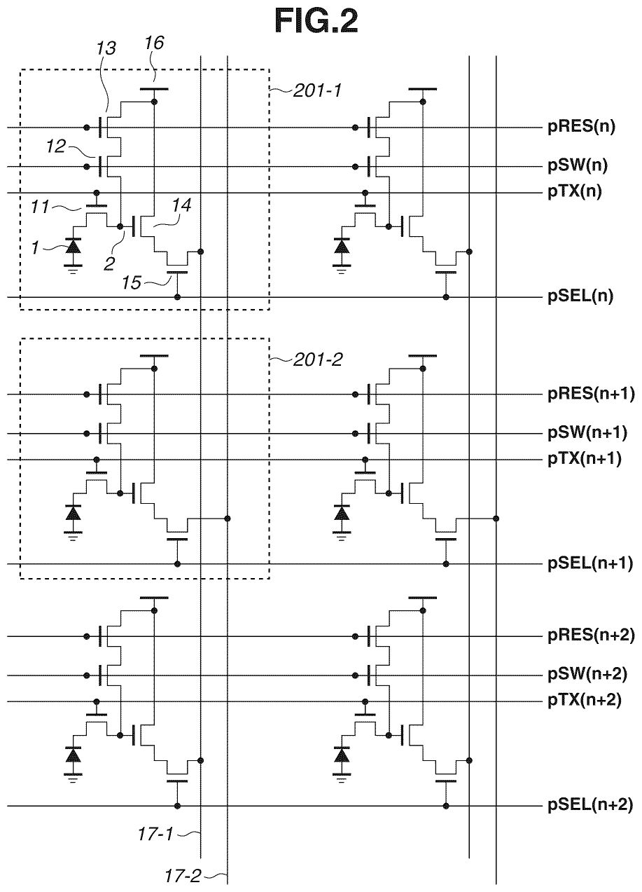

FIG. 2 is an equivalent circuit diagram of pixels included in the photoelectric conversion region 102. While, in FIG. 2, a 3×2 (3 rows by 2 columns) configuration is illustrated for the sake of simplification, the number of pixels is not limited thereto.

While two signal lines 17-1 and 17-2 are disposed for a single column, the number of signal lines is not limited thereto.

A pixel 201 includes a photoelectric conversion unit 1, a floating diffusion unit 2, and a transfer unit 11 disposed between the photoelectric conversion unit 1 and the floating diffusion unit 2. The pixel 201 also includes a capacitance changing unit 12 for changing the capacitance of the floating diffusion unit 2 as required. The pixel 201 also includes a reset unit 13 for resetting the floating diffusion unit 2, and an amplifying unit 14 for outputting a signal from the floating diffusion unit 2. The pixel 201 further includes a selection unit 15 for controlling the signal output from the amplifying unit 14 to the signal line 17. Each of the transfer unit 11, the capacitance changing unit 12, the reset unit 13, the amplifying unit 14, and the selection unit 15 uses a transistor, for example. While metal oxide semiconductor (MOS) transistors are typically used, the form is not limited thereto. While the following exemplary embodiments employ an N-type MOS transistor, the conductivity type can be suitably changed as described above.

The photoelectric conversion unit 1 receives light incident on the pixel 201 and produces electric charges corresponding to the amount of received light. For example, a photodiode is usable as the photoelectric conversion unit 1. The floating diffusion unit 2 temporarily stores electric charges transferred from the photoelectric conversion unit 1 and at the same time functions as an electric charge voltage conversion unit for converting the stored electric charges into a voltage signal.

The transfer unit 11 is driven by a transfer unit drive pulse pTX and transfers the electric charge generated by the photoelectric conversion unit 1 to the floating diffusion unit 2.

The capacitance changing unit 12 is driven by a capacitance changing pulse pSW of the floating diffusion and changes the capacitance of the floating diffusion unit 2.

When the capacitance changing unit 12 is turned ON, the gate capacitance of the capacitance changing unit 12 is added to the floating diffusion unit 2.

The reset unit 13 is driven by a reset unit drive pulse pRES. At the driving timing, when the reset unit 13 and the capacitance changing unit 12 are turned ON at the same time, the floating diffusion unit 2 is reset. The reset unit 13 is connected to a power supply line 16 configured to supply a voltage to the reset transistor.

The amplifying unit 14 amplifies the voltage signal converted by the floating diffusion unit 2 and outputs the signal as a pixel signal. The amplifying unit 14 includes an amplifying transistor having the gate, drain, and source.

The selection unit 15 is driven by a selection drive pulse pSEL and outputs the pixel signal amplified by the amplifying unit 14 to the signal line 17-1 or 17-2. The selection unit 15 includes a selection transistor having the gate, drain, and source. According to the present exemplary embodiment, signal lines are vertical signal lines extending in the vertical direction, and the selection unit 15 is driven by a row selection pulse. The present disclosure also includes a case where signal lines are horizontal signal lines extending in the horizontal direction.

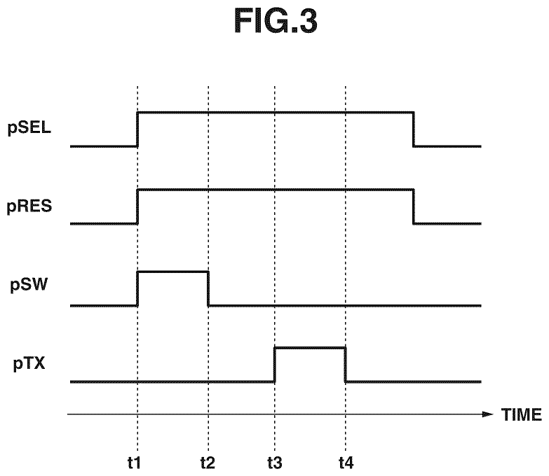

FIG. 3 is a timing chart illustrating different drive pulses in the photoelectric conversion apparatus 101. In FIG. 3, as an example, a timing chart of a pixel signal that is output with low luminance is illustrated. In FIG. 3, the horizontal axis indicates time t and the vertical axis indicates the voltage.

At time t1, the capacitance changing unit 12, the reset unit 13, and the selection unit 15 are turned ON. This selects a pixel and resets the floating diffusion unit 2.

At time t2, the capacitance changing unit 12 is turned OFF while the reset unit 13 and the selection unit 15 are kept ON. This reduces the capacitance of the floating diffusion unit 2 during the readout time, which reduces noise. In this process, the signal output to the signal line 17 via the amplifying unit 14 is output to the output unit 106 as a reset level signal.

At time t3, the transfer unit 11 is turned ON to transfer the electric charges accumulated in the photoelectric conversion unit 1 to the floating diffusion unit 2.

At time t4, the transfer unit 11 is turned OFF, and the signal output to the signal line 17 via the amplifying unit 14 is output as a pixel signal to the output unit 106.

Then, the reset unit 13 and the selection unit 15 are turned OFF.

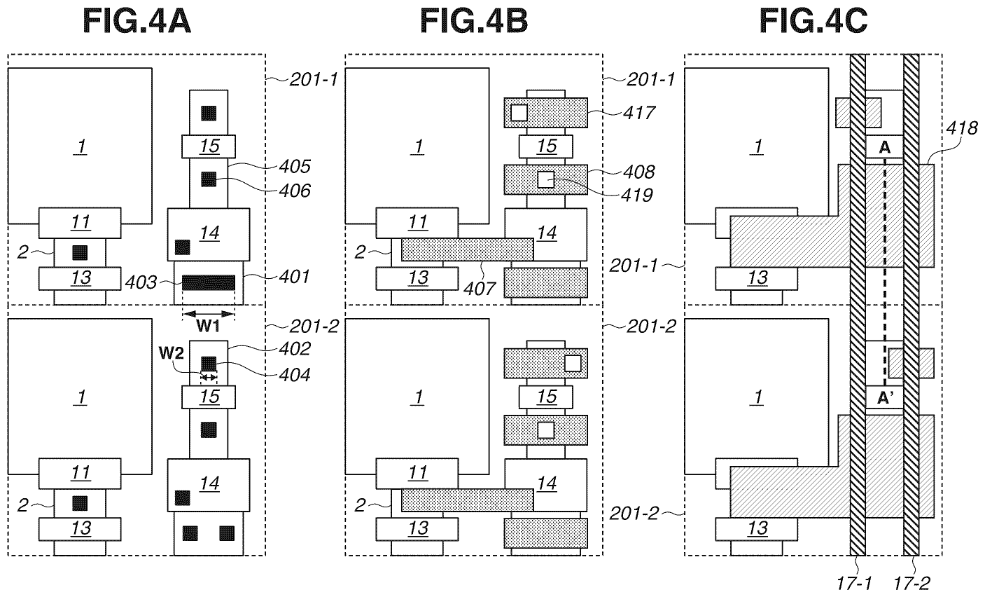

FIG. 4A is a plan view illustrating the pixels 201 according to the first exemplary embodiment. FIG. 4A illustrates a layout of diffusion regions and gates of transistors in the semiconductor layer. According to the present exemplary embodiment, the photoelectric conversion apparatus 101 is a rear surface irradiation photoelectric conversion apparatus in which light is radiated from below the semiconductor layer, i.e., from the side opposite to the side where a first wiring layer is disposed in the semiconductor layer. Referring to FIGS. 4A, 4B, and 4C, elements same as or corresponding to those in FIG. 2 are assigned the same reference numerals. While, in FIGS. 4A, 4B, and 4C, each region is illustrated in a rectangular form for simplification, the shape of each unit is not limited thereto. The rectangular form indicates at least that each unit is disposed in the relevant region.

A diffusion region 401 is the drain region of the amplifying unit 14, and a diffusion region 402 (second diffusion region) is the source region of the selection unit 15. The diffusion region 401 is connected to a contact 403 (first contact). The diffusion region 402 is connected to a contact 404 (second contact). A diffusion region 405 is connected to a contact 406.

The gate of the amplifying unit 14 and the diffusion regions 401 and 402 are adjacently disposed on a straight line in a gate length direction of the amplifying unit 14 (vertical direction in the drawing). The gate length direction of the amplifying unit 14 is also referred to as a first direction.

The contact 404 has a size (width) W2 in a direction parallel to a gate width direction of the amplifying unit 14 (horizontal direction in the drawing). A direction perpendicularly intersecting with the first direction is also referred to as a second direction. The contact 403 has a horizontal size W1. W1 and W2 are different and have a relation W1>W2. The contact 403 interrupts the electrical coupling between the contact 404 and the gate of the amplifying unit 14, which reduces a parasitic capacitance that occurs between the floating diffusion unit 2 and the contact 404. As a result, in the photoelectric conversion apparatus 101 having a mode for reading the pixels 201-1 and 201-2 at the same time, crosstalk from the output of the pixel 201-2 to the floating diffusion unit 2 is prevented, whereby the image quality is improved.

The width of the gate of the amplifying unit 14 in the first direction is larger than the length of the gate of the amplifying unit 14 in the second direction. This means that a larger width of the gate provides more remarkable effects of the crosstalk prevention according to the present exemplary embodiment.

FIG. 4B is a plan view illustrating the pixels 201 according to the first exemplary embodiment. FIG. 4B illustrates a layout of the first wiring layer disposed as the upper layer of the semiconductor layer illustrated in FIG. 4A.

A wiring 407 (first wiring) is connected to the floating diffusion unit 2 and the gate of the amplifying unit 14. A wiring 408 (second wiring) is connected to the diffusion region 405 via the contact 406. A via 419 is connected to the wiring 408. A wiring 417 is connected to the drain region of the selection unit 15.

FIG. 4C is a plan view illustrating the pixels 201 according to the first exemplary embodiment. FIG. 4C illustrates a layout of a second wiring layer disposed as the upper layer of the first wiring layer illustrated in FIG. 4B, and a layout of a third wiring layer disposed as the upper layer of the second wiring layer. Wirings mainly made of copper are used as wirings included in the first, the second, and the third wiring layers. These wirings may further include a barrier metal layer in which titanium and nickel are used.

A shield wiring 418 is disposed in the second wiring layer and connected with the wiring 408 via the via 419. The signal lines 17-1 and 17-2 are disposed in the third wiring layer. The shield wiring 418 is disposed in a position where the signal lines 17-1 and 17-2 overlap with the gate of the amplifying unit 14 in a planar view. It is desirable that the shield wiring 418 is disposed to cover the gate of the amplifying unit 14 and the wiring 407. This reduces a parasitic capacitance. Alternatively, the shield wiring 418 may cover at least a part of the gate of the amplifying unit 14.

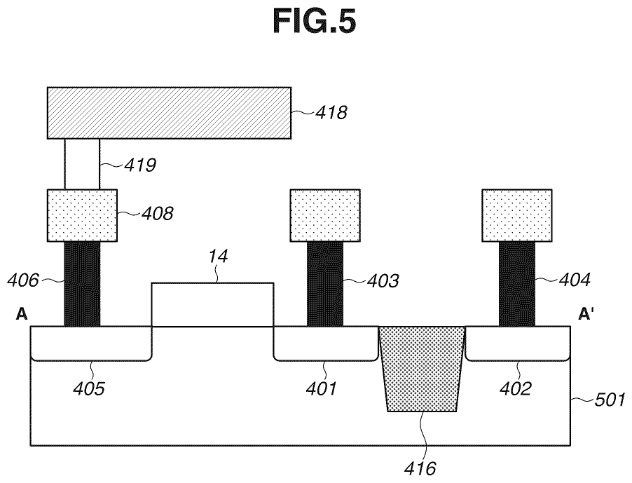

FIG. 5 is a cross-sectional view taken along the A-A′ line of FIG. 4C. The diffusion regions 401, 402, and 405 are disposed in a semiconductor layer 501. An element isolation region 416 is disposed between the diffusion regions 401 and 402. FIG. 5 illustrates an example where the element isolation region 416 is an oxide film for element isolation, such as Shallow Trench Isolation (STI). The aspect of the embodiments is not limited thereto. The element isolation region 416 may be a diffusion region having a conductivity type different from the conductivity type of the diffusion regions 401 and 402.

According to the present exemplary embodiment, the gate of the amplifying unit 14 and the diffusion region 401s and 402 are adjacently disposed on a straight line in the gate length direction of the amplifying unit 14, and the contact width relation is set to W1>W2, whereby the image quality is improved.

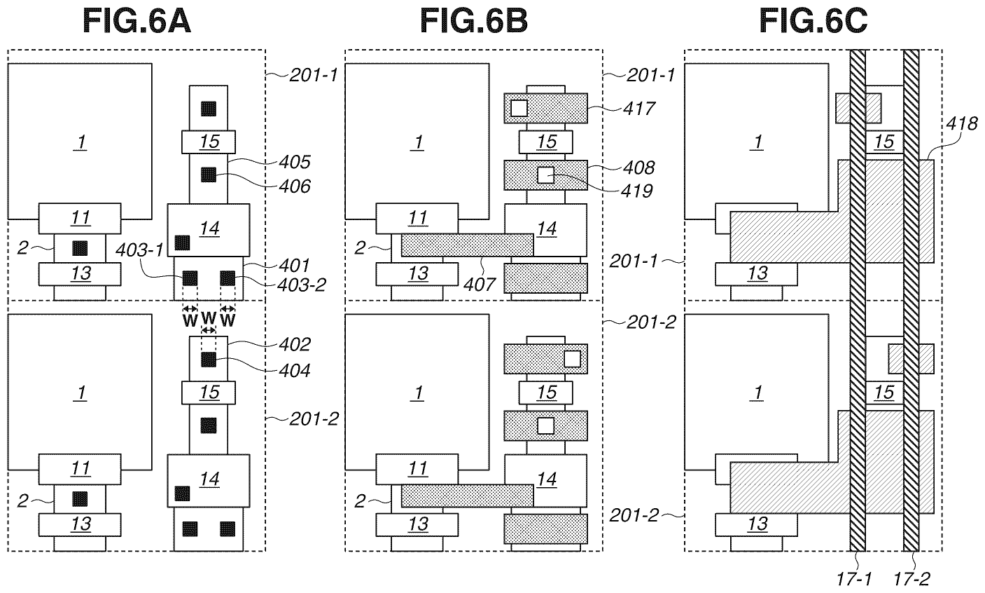

FIGS. 6A to 6C are plan views illustrating pixels according to a second exemplary embodiment. The present exemplary embodiment differs from the first exemplary embodiment in that a plurality of contacts 403-1 and 403-2 is connected to the diffusion region 401, and has substantially the same structures of other elements as the first exemplary embodiment. Only differences from the first exemplary embodiment will be described below, and descriptions of the same structures as the first exemplary embodiment will be suitably omitted.

FIG. 6A is a plan view illustrating the pixels 201 according to the second exemplary embodiment. FIG. 6A illustrates a layout of diffusion regions and gates of transistors in the semiconductor layer. The diffusion region 401 is the drain region of the amplifying unit 14, and the diffusion region 402 is the source region of the selection unit 15. The gate of the amplifying unit 14 and the diffusion regions 401 and 402 are adjacently disposed on a straight line in the gate length direction of the amplifying unit 14 (vertical direction in the drawing).

Two contacts, i.e., the contacts 403-1 and 403-2, horizontally arranged side by side are connected to the diffusion region 401, and one contact, i.e., the contact 404, is connected to the diffusion region 402. According to the present exemplary embodiment, the number of contacts 403 is more than the number of contacts 404, and the sum of the widths of the contacts 403 is longer than the width of the contact 404. The numbers of contacts are not limited thereto as long as the number of contacts 403 is more than the number of contacts 404. The diffusion region 405 is the source region of the amplifying unit 14to which the contact 406 is connected.

FIG. 6B is a plan view illustrating the pixels 201 according to the second exemplary embodiment. FIG. 6B illustrates a layout of the first wiring layer disposed as the upper layer of the semiconductor layer illustrated in FIG. 6A. The wiring 407 is connected to the floating diffusion unit 2 and the gate of the amplifying unit 14. The wiring 408 is connected to the diffusion region 405 via the contact 406. The via 419 is connected to the wiring 408. The wiring 417 is connected to the drain region of the selection unit 15.

FIG. 6C is a plan view illustrating the pixels 201 according to the second exemplary embodiment. FIG. 6C illustrates a layout of the second wiring layer disposed as the upper layer of the first wiring layer illustrated in FIG. 6B, and a layout of the third wiring layer disposed as the upper layer of the second wiring layer.

The shield wiring 418 is disposed in the second wiring layer and connected to the wiring 408 via the via 419. The signal lines 17-1 and 17-2 are disposed in the third wiring layer. The shield wiring 418 is disposed in a position where the signal lines 17-1 and 17-2 overlap with the gate of the amplifying unit 14 in a planar view. It is desirable that the shield wiring 418 is disposed to cover the gate of the amplifying unit 14 and the wiring 407. This reduces a parasitic capacitance. Alternatively, the shield wiring 418 may cover at least a part of the gate of the amplifying unit 14.

According to the present exemplary embodiment, the sum of the horizontal sizes of the contacts 404 is W, and the sum of the horizontal sizes of the contacts 403 is 2×W, which is longer than W. Thus, the contacts 403-1 and 403-2 interrupt the electrical coupling between the contact 404 and the gate of the amplifying unit 14, which reduces a parasitic capacitance that occurs between the floating diffusion unit 2 and the contact 404. As a result, in the photoelectric conversion apparatus 101 having a mode for reading the pixels 201-1 and 201-2 at the same time, crosstalk from the output of the pixel 201-2 to the floating diffusion unit 2 of the pixel 201-1 is prevented, whereby the image quality is improved.

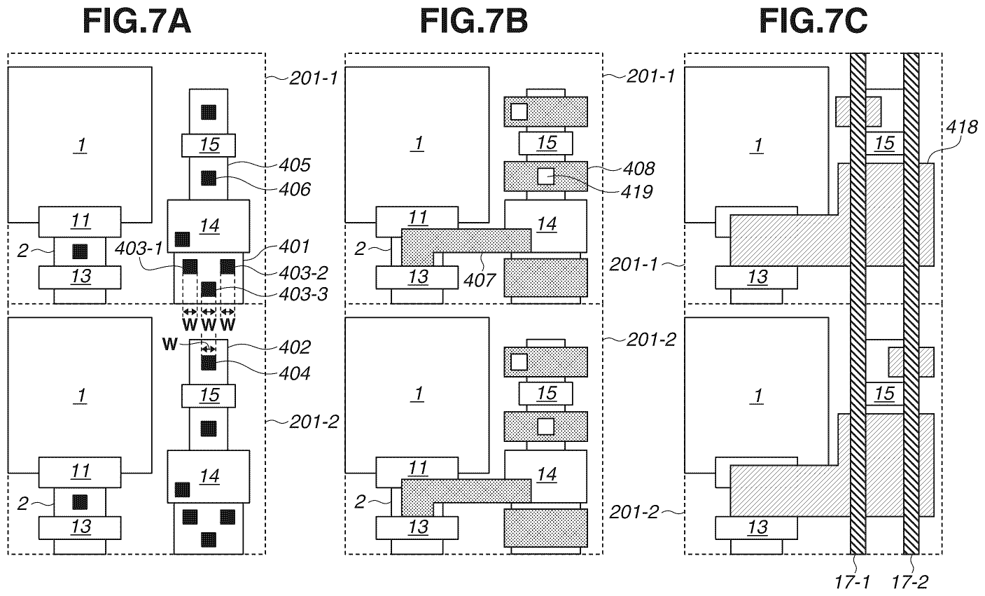

FIGS. 7A to 7C are plan views illustrating pixels according to a third exemplary embodiment. The present exemplary embodiment differs from the second exemplary embodiment in that three different contacts, i.e., contacts 403-1, 403-2, and 403-3 are connected to the diffusion region 401, and has substantially the same structures of other elements as the second exemplary embodiment. Differences from the second exemplary embodiment will be described below, and descriptions of the same structures as the second exemplary embodiment will be suitably omitted.

According to the present exemplary embodiment, as illustrated in FIG. 7A, the three different contacts, i.e., the contacts 403, are connected to the diffusion region 401, and two out of the three different contacts are disposed on a straight line in the horizontal direction. One contact, i.e., the contact 404, is connected to the diffusion region 402. The number of contacts is not limited thereto as long as at least two out of the three different contacts, i.e., at least two out of the contacts 403, are disposed on a straight line in the horizontal direction. When viewed from the contact 404, the contact 403-3 is disposed between the contacts 403-1 and 403-2. With this configuration, the electrical coupling between the gate of the amplifying unit 14 and the contact 404 is more easily interrupted than in the second exemplary embodiment.

FIG. 7B illustrates a layout of the first wiring layer disposed as the upper layer of the semiconductor layer illustrated in FIG. 7A. FIG. 7C illustrates a layout of the second wiring layer disposed as the upper layer of the first wiring layer illustrated in FIG. 7B, and a layout of the third wiring layer disposed as the upper layer of the second wiring layer.

According to the present exemplary embodiment, the sum of the horizontal sizes of the contacts 404 is W, and the sum of the horizontal sizes of the contacts 403 is ×W, which is longer than W. Thus, the contacts 403-1, 403-2, and 403-3 interrupt the electrical coupling between the contact 404 and the gate of the amplifying unit 14, which reduces a parasitic capacitance that occurs between the floating diffusion unit 2 and the contact 404. As a result, in the photoelectric conversion apparatus 101 having a mode for reading the pixels 201-1 and 201-2 at the same time, crosstalk from the output of the pixel 201-2 to the floating diffusion unit 2 of the pixel 201-1 is prevented, whereby the image quality is improved.

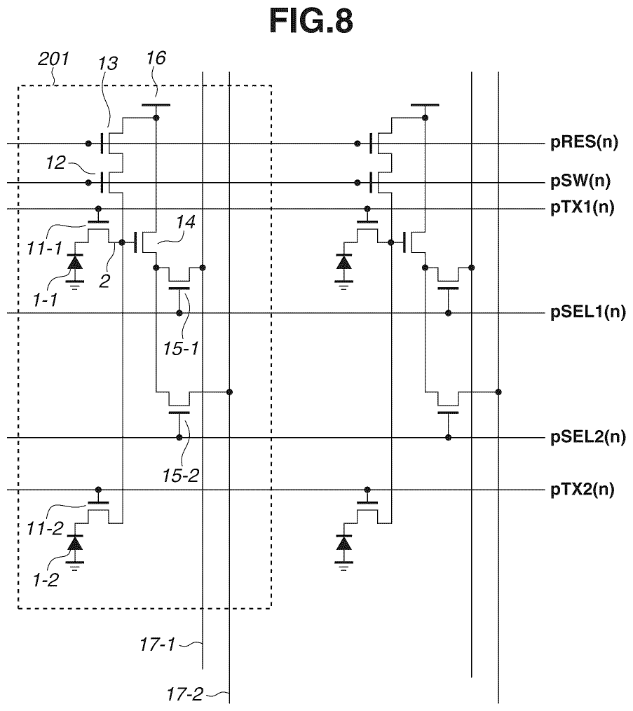

FIG. 8 is an equivalent circuit diagram of pixels included in the photoelectric conversion region 102 according to a fourth exemplary embodiment.

The present exemplary embodiment differs from the second exemplary embodiment in that two different photoelectric conversion units, i.e., photoelectric conversion units 1-1 and 1-2 are shared by one floating diffusion unit 2, and two different selection units, i.e., selection units 15-1 and 15-2 are connected to the output of one amplifying unit, i.e., the amplifying unit 14, and has substantially the same structures of other elements as the second exemplary embodiment. Differences from the second exemplary embodiment will be described below, and descriptions of the same structures as the second exemplary embodiment will be suitably omitted.

In the pixel 201 according to the present exemplary embodiment, the two different photoelectric conversion units, i.e., the photoelectric conversion units 1-1 and 1-2, are shared by the one floating diffusion unit, i.e., the floating diffusion unit 2. Further, the two different photoelectric conversion units, i.e., the selection units 15-1 and 15-2, are connected to the output of the one amplifying unit, i.e., the amplifying unit 14. The number of photoelectric conversion units shared by one floating diffusion is not limited thereto. The number of selection units 15 connected to the one amplifying unit is not limited thereto.

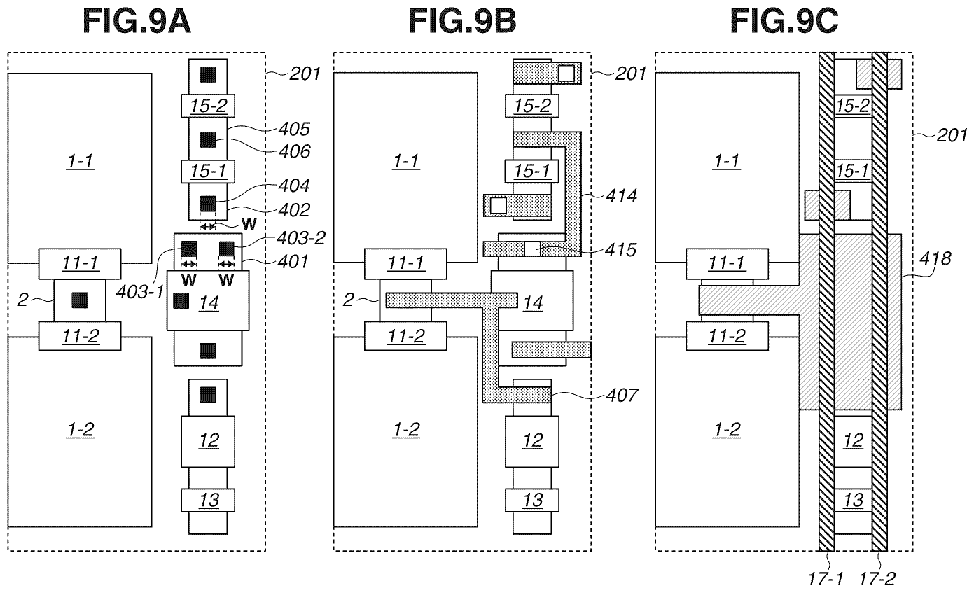

FIG. 9A is a plan view illustrating the pixel 201 according to the present exemplary embodiment. FIG. 9A illustrates a layout of diffusion regions and gates of transistors in the semiconductor layer. The diffusion region 401 is the source region of the amplifying unit 14, and the diffusion region 402 is the source region of the selection unit 15.

The diffusion regions 402 and 401 and the gate of the amplifying unit 14 are adjacently disposed on a straight line in the gate length direction of the amplifying unit 14 (vertical direction in the drawing).

The two different contacts, i.e., the contacts 403-1 and 403-2 horizontally arranged side by side are connected to the diffusion region 401, and one contact 404 is connected to the diffusion region 402. According to the present exemplary embodiment, the number of contacts 403 is more than the number of contacts 404, and the sum of the widths of the contacts 403 is longer than the width of the contact 404. The numbers of contacts are not limited thereto as long as the number of contacts 403 is more than the number of contacts 404. The diffusion region 405 is the drain region of the selection unit 15 and connected to the contact 406.

FIG. 9B is a plan view illustrating the pixel 201 according to the present exemplary embodiment. FIG. 9B illustrates a layout of the first wiring layer disposed as the upper layer of the semiconductor layer illustrated in FIG. 9A. The wiring 407 is connected to the floating diffusion unit 2 and the gate of the amplifying unit 14. A wiring 414 is connected to the diffusion region 401 via the contacts 403-1 and 403-2. The wiring 414 is connected to the drain region of the selection unit 15. A via 415 is connected to the wiring 414.

FIG. 9C is a plan view illustrating the pixel 201 according to the present exemplary embodiment. FIG. 9C illustrates a layout of the second wiring layer disposed as the upper layer of the first wiring layer illustrated in FIG. 9B, and a layout of the third wiring layer disposed as the upper layer of the second wiring layer. The shield wiring 418 is connected to the wiring 414 via the via 415. The signal lines 17-1 and 17-2 are disposed in the third wiring layer. The shield wiring 418 is disposed in a position where the signal lines 17-1 and 17-2 overlap with the gate of the amplifying unit 14 in a planar view. It is desirable that the shield wiring 418 is disposed to cover the gate of the amplifying unit 14 and the wiring 407. Alternatively, the shield wiring 418 may cover at least a part of the gate of the amplifying unit 14.

According to the present exemplary embodiment, the sum of the horizontal sizes of the contacts 404 is W, and the sum of the horizontal sizes of the contacts 403-1 and 403-2 is 2 x W, which is more than W. Thus, the contact 403 interrupts the electrical coupling between the contact 404 and the gate of the amplifying unit 14, which reduces a parasitic capacitance that occurs between the floating diffusion unit 2 and the contact 404. As a result, in the photoelectric conversion apparatus 101 having a mode for reading by using the signal lines 17-1 and 17-2 at the same time, crosstalk from the output of the signal line 17-1 to the floating diffusion unit 2 is prevented, whereby the image quality is improved.

According to the present exemplary embodiment, as illustrated in FIGS. 4A to 4C, one horizontally long contact 403 or at least three different contacts 403 illustrated in FIGS. 7A to 7C are also applicable.

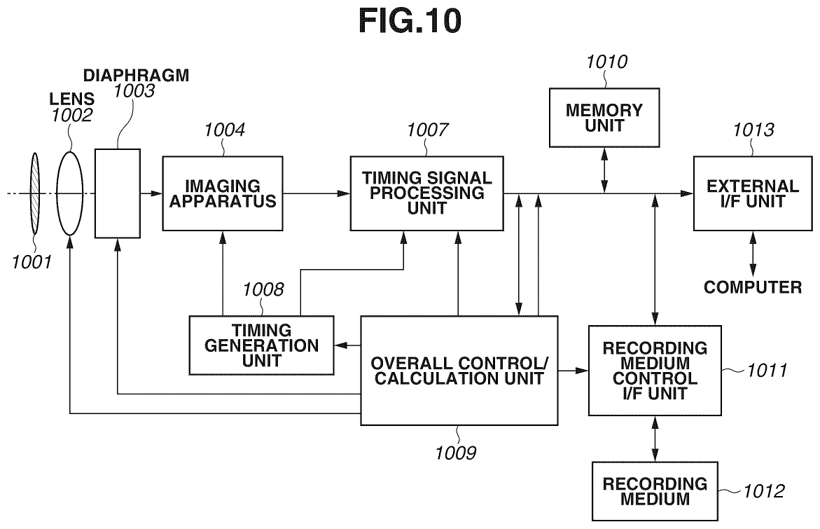

With reference to FIG. 10, a photoelectric conversion system according to a fifth exemplary embodiment is described. FIG. 10 is a block diagram illustrating a general configuration of the photoelectric conversion system according to the present exemplary embodiment.

The photoelectric conversion apparatus (imaging apparatus) described in each of the first and fourth exemplary embodiments is applicable to various photoelectric conversion systems. Examples of the various photoelectric conversion systems include a digital still camera, a digital camcorder, a monitoring camera, a copying machine, a fax, a mobile phone, an in-vehicle camera, and an observation satellite. The various photoelectric conversion systems also include a camera module including an optical system, such as a lens and an imaging apparatus. FIG. 10 illustrates a block diagram of a digital still camera as one of these examples.

The photoelectric conversion system illustrated in FIG. 10 includes an imaging apparatus 1004, which is an example of the photoelectric conversion apparatus, and a lens 1002 that forms an optical image of a subject on the imaging apparatus 1004. The imaging apparatus 1004 further includes a diaphragm 1003 for varying an amount of light passing through the lens 1002, and a barrier 1001 for protecting the lens 1002. The lens 1002 and the diaphragm 1003 serves as an optical system that collects light onto the imaging apparatus 1004. The imaging apparatus 1004 is the photoelectric conversion apparatus according to any of the above-described exemplary embodiments and converts the optical image formed by the lens 1002 into an electric signal.

The photoelectric conversion system further includes a signal processing unit 1007 serving as an image generation unit that processes an output signal output from the imaging apparatus 1004, to generate an image. The signal processing unit 1007 performs an operation of performing various types of correction and compression as necessary and outputting image data. The signal processing unit 1007 may be formed on a semiconductor substrate in which the imaging apparatus 1004 is disposed, or may be formed on a semiconductor substrate different from the imaging apparatus 1004. The imaging apparatus 1004 and the signal processing unit 1007 may be formed on the same semiconductor substrate.

The photoelectric conversion system further includes a memory unit 1010 for temporarily storing image data, and an external interface unit (external I/F unit) 1013 for communicating with an external computer. The photoelectric conversion system further includes a recording medium 1012, such as a semiconductor memory, for recording therein or reading therefrom captured data, and a recording medium control interface unit (recording medium control I/F unit) 1011 for recording or reading image data in or from the recording medium 1012. The recording medium 1012 may be built into the photoelectric conversion system or may be attachable to and detachable from the photoelectric conversion system.

Further, the photoelectric conversion system according to the present exemplary embodiment includes an overall control/calculation unit 1009 that performs various calculations and controls the entire operation of the digital still camera, and a timing signal generation unit 1008 that outputs various timing signals to the imaging apparatus 1004 and the signal processing unit 1007. The timing signals may be input from outside, and the photoelectric conversion system may be required to include at least the imaging apparatus 1004 and the signal processing unit 1007 that processes an output signal output from the imaging apparatus 1004.

The imaging apparatus 1004 outputs an imaging signal to the signal processing unit 1007. The signal processing unit 1007 performs predetermined signal processing on the imaging signal output from the imaging apparatus 1004 and outputs image data. The signal processing unit 1007 generates an image using the imaging signal.

As described above, according to the present exemplary embodiment, it is possible to achieve a photoelectric conversion system to which the photoelectric conversion apparatus (the imaging apparatus) according to any of the above-described exemplary embodiments is applied.

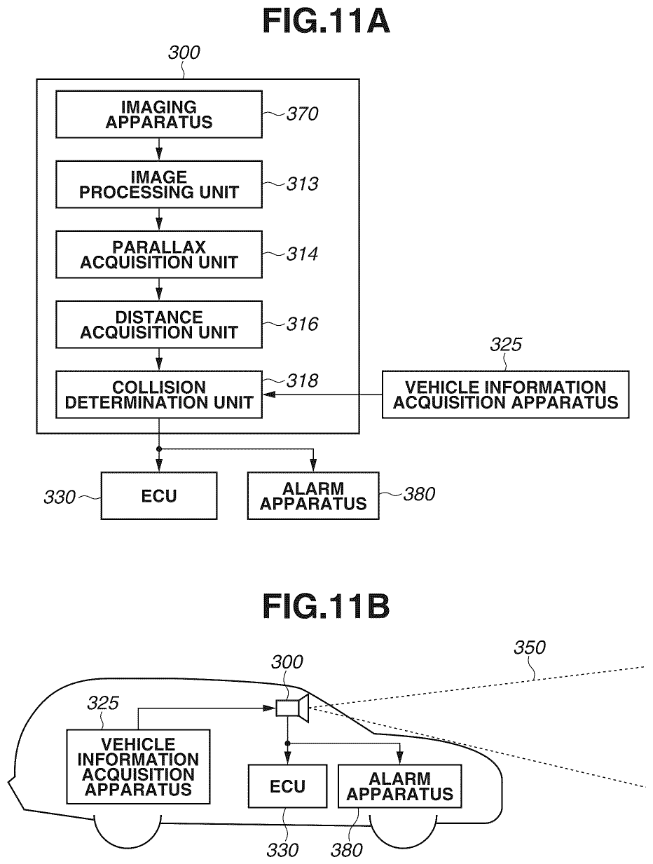

With reference to FIGS. 11A and 11B, a photoelectric conversion system and a movable body according to a sixth exemplary embodiment are described. FIGS. 11A and 11B are diagrams illustrating the configurations of the photoelectric conversion system and the movable body according to the present exemplary embodiment.

FIG. 11A illustrates an example of a photoelectric conversion system regarding an in-vehicle camera. A photoelectric conversion system 300 includes an imaging apparatus 370. The imaging apparatus 370 is the photoelectric conversion apparatus according to each of the first to fourth exemplary embodiments. The photoelectric conversion system 300 includes an image processing unit 313 that performs image processing on a plurality of pieces of image data acquired by the imaging apparatus 370, and a parallax acquisition unit 314 that calculates a parallax (phase difference between parallax images) from the plurality of pieces of image data acquired by the photoelectric conversion system 300. The photoelectric conversion system 300 further includes a distance acquisition unit 316 that measures a distance from a target object based on the calculated parallax, and a collision determination unit 318 that determines whether there is a possibility of a collision, based on the calculated distance. The parallax acquisition unit 314 and the distance acquisition unit 316 are examples of a distance information acquisition unit that acquires distance information regarding the distance from a target object. That is, the distance information is information regarding the parallax, the amount of defocus, and the distance from the target object. Any of these pieces of distance information may be used by the collision determination unit 318 to determine the possibility of a collision. The distance information acquisition unit may be achieved by exclusively designed hardware, or may be achieved by a software module. Alternatively, the distance information acquisition unit may be achieved by a field-programmable gate array (FPGA) or an application-specific integrated circuit (ASIC), or may be achieved by the combination of these.

The photoelectric conversion system 300 is connected to a vehicle information acquisition apparatus 325 and can acquire vehicle information, such as a vehicle speed, a yaw rate, and a steering angle. The photoelectric conversion system 300 is also connected to a control electronic control unit (ECU) 330 that is a control apparatus that produces a braking force in the vehicle based on a determination result of the collision determination unit 318. The photoelectric conversion system 300 is also connected to an alarm apparatus 380 that gives an alarm to a driver based on a determination result of the collision determination unit 318. For example, if there is a high possibility of a collision as the determination result of the collision determination unit 318, the control ECU 330 performs braking, releasing an accelerator, or suppressing engine output, to control the vehicle to avoid a collision and reduce damage. The alarm apparatus 380 warns a user by setting off an alarm such as a sound, displaying alarm information on a screen of an automotive navigation system, or imparting a vibration to a seat belt or the steering.

In the present exemplary embodiment, the photoelectric conversion system 300 captures the periphery, such as the front direction or the rear direction, of the vehicle. FIG. 11B illustrates the photoelectric conversion system 300 in a case where the photoelectric conversion system 300 captures the front direction of the vehicle (an imaging range 2350). The vehicle information acquisition apparatus 325 sends an instruction to the photoelectric conversion system 300 or the imaging apparatus 370. With this configuration, the accuracy of distance measurement can be further improved.

In the above description, an example has been described where a vehicle is controlled to avoid colliding with another vehicle. Alternatively, the present exemplary embodiment is also applicable to control for autonomous driving to follow another vehicle or control for autonomous driving to avoid a deviation from a lane. Furthermore, the photoelectric conversion system can be applied not only to a vehicle such as an automobile but also to a movable body (a moving apparatus), such as a vessel, an aircraft, or an industrial robot. The moving body includes one or both a driving force generation unit that generates a driving force mainly for movement of the moving body and a rotating body mainly for movement of the moving body. The driving force generation unit may be an engine, a motor, or the like. The rotating body may be a tire, a wheel, a screw of a ship, a propeller of a flying object, or the like. Moreover, in addition to a movable body, the photoelectric conversion system can be applied to an equipment extensively using object recognition, such as an intelligent transportation system (ITS).

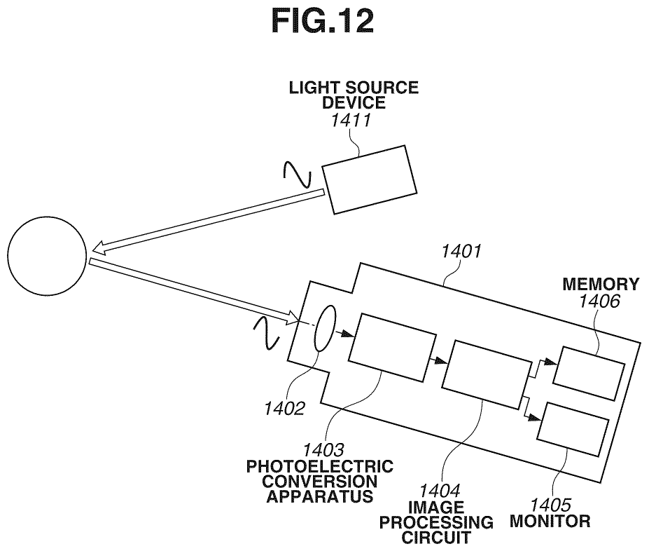

With reference to FIG. 12, a photoelectric conversion system according to a seventh exemplary embodiment is described. FIG. 12 is a block diagram illustrating an example of the configuration of a distance image sensor that includes the photoelectric conversion system according to the present exemplary embodiment.

As illustrated in FIG. 12, a distance image sensor 1401 includes an optical system 1402, a photoelectric conversion apparatus 1403, an image processing circuit 1404, a monitor 1405, and a memory 1406. Then, the distance image sensor 1401 acquires a distance image corresponding to a distance from a subject by receiving light (modulated light or pulsed light) that has been projected from a light source device 1411 toward the subject and reflected from the surface of the subject.

The optical system 1402 includes one or more lenses and forms an image on a light-receiving surface (a sensor unit) of the photoelectric conversion apparatus 1403 by guiding image light (incident light) from the subject to the photoelectric conversion apparatus 1403.

As the photoelectric conversion apparatus 1403, the photoelectric conversion apparatus according to each of the first to fourth exemplary embodiments is applied, and a distance signal indicating the distance obtained from a received light signal output from the photoelectric conversion apparatus 1403 is supplied to the image processing circuit 1404.

The image processing circuit 1404 performs image processing to construct a distance image based on the distance signal supplied from the photoelectric conversion apparatus 1403. Then, the distance image (image data) obtained by the image processing is supplied to and displayed on the monitor 1405 or is supplied to and stored (recorded) in the memory 1406.

Application of the above-described photoelectric conversion apparatus to the distance image sensor 1401 having the above-describe configuration leads to achievement of acquiring a more accurate distance image, for example, in accordance with the improved characteristics of pixels.

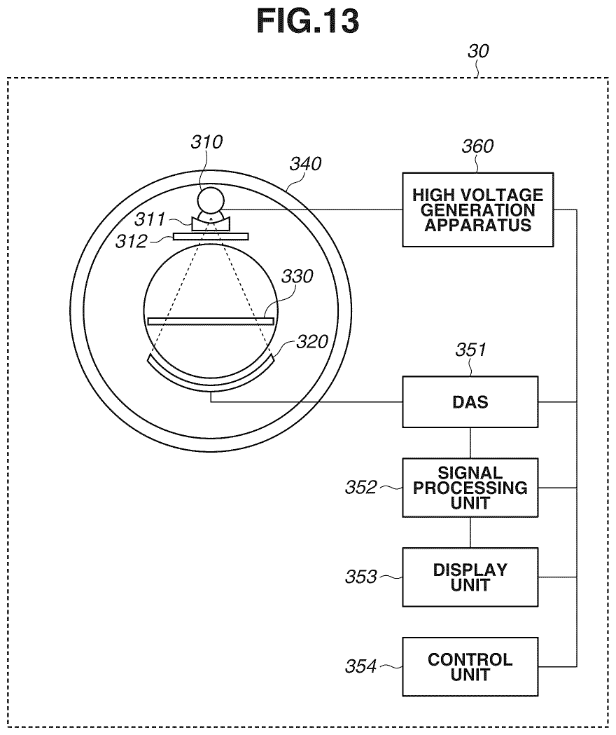

FIG. 13 is a block diagram of an X-ray computer tomography (CT) apparatus according to an eighth exemplary embodiment. The photoelectric conversion apparatus according to each of the first to fourth exemplary embodiments can be applied to a detection unit of an X-ray CT apparatus. An X-ray CT apparatus 30 according to the present exemplary embodiment includes an X-ray generation unit 310, a wedge 311, a collimator 312, an X-ray detection unit 320, a top board 330, a rotation frame 340, and a high voltage generation apparatus 360. The X-ray CT apparatus 30 includes a data collection apparatus (data acquisition system: DAS) 351, a signal processing unit 352, a display unit 353, and a control unit 354.

The X-ray generation unit 310 includes a vacuum tube that generates X-rays, for example. High voltage and filament current from the high voltage generation apparatus 360 are supplied to the vacuum tube of the X-ray generation unit 310. By thermal electrons being emitted from a negative pole (filament) toward a positive pole (target), X-rays are generated.

The wedge 311 is a filter that adjusts an amount of X-rays emitted from the X-ray generation unit 310. The wedge 311 attenuates an X-ray amount in such a manner that X-rays emitted from the X-ray generation unit 310 to a subject have a predetermined distribution. The collimator 312 includes a lead plate that narrows down an emission range of X-rays that have passed through the wedge 311. The X-rays generated by the X-ray generation unit 310 are formed into a cone-beam shape via the collimator 312 and emitted to a subject on the top board 330.

The X-ray detection unit 320 includes the photoelectric conversion apparatus according to each of the first to fourth exemplary embodiments. The X-ray detection unit 320 detects X-rays that have been generated by the X-ray generation unit 310 and passed through the subject, and outputs a signal corresponding to an X-ray amount, together with the DAS 351.

The rotation frame 340 has an annular shape and is configured to be rotatable. In the rotation frame 340, the X-ray generation unit 310 (wedge 311, collimator 312) and the X-ray detection unit 320 are disposed to face each other. The X-ray generation unit 310 and the X-ray detection unit 320 are rotatable together with the rotation frame 340.

The high voltage generation apparatus 360 includes a booster circuit, and outputs high voltage to the X-ray generation unit 310. The DAS 351 includes an amplification circuit and an analog-to-digital (A/D) conversion circuit, and outputs a signal from the X-ray detection unit 320 to the signal processing unit 352 as digital data.

The signal processing unit 352 includes a central processing unit (CPU), a read only memory (ROM), and a random access memory (RAM), and executes image processing on digital data. The display unit 353 includes a flat-panel display device, and displays an X-ray image. The control unit 354 includes a CPU, a ROM, and a RAM, and controls entire operations of the X-ray CT apparatus 30.

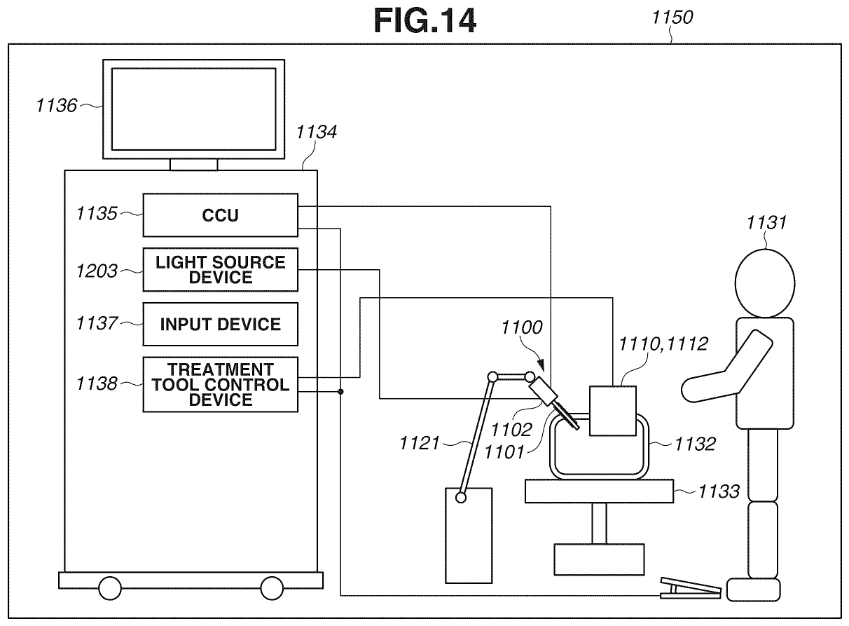

With reference to FIG. 14, a photoelectric conversion system according to a ninth exemplary embodiment is described. FIG. 14 is a diagram illustrating an example of the general configuration of an endoscopic operation system that is the photoelectric conversion system according to the present exemplary embodiment.

FIG. 14 illustrates the state where a user (doctor) 1131 performs a surgery on a patient 1132 on a patient bed 1133 using an endoscopic operation system 1150. As illustrated in FIG. 27, the endoscopic operation system 1150 includes an endoscope 1100, surgical tools 1110, and a cart 1134 equipped with various devices for an endoscopic operation.

The endoscope 1100 includes a lens barrel 1101 having a part to be inserted into a body cavity of a patient 1132 by a predetermined length from its front end, and a camera head 1102 connected to the base end of the lens barrel 1101. While, in the example illustrated in FIG. 27, the endoscope 1100 configured as a so-called rigid scope including the lens barrel 1101 which is rigid, the endoscope 1100 may be configured as a so-called flexible scope including a flexible lens barrel.

An opening portion into which an objective lens is fitted is at the front end of the lens barrel 1101. A light source device 1203 is connected to the endoscope 1100. Light generated by the light source device 1203 is guided to the front end of the lens barrel 1101 by a light guide extended inside the lens barrel 1101, passes through the objective lens, and is emitted toward an observation target in the body cavity of the patient 1132. The endoscope 1100 may be a forward-viewing endoscope, or may be an oblique-viewing endoscope, or may be a side-viewing endoscope.

An optical system and a photoelectric conversion apparatus are disposed inside the camera head 1102, and reflected light (observation light) from the observation target is collected on the photoelectric conversion apparatus by the optical system. The observation light is photoelectrically converted by the photoelectric conversion apparatus, and an electric signal corresponding to the observation light, i.e., an image signal corresponding to an observation image, is generated. The photoelectric conversion apparatus according to each of the above-described exemplary embodiments can be used as the photoelectric conversion apparatus (imaging apparatus). The image signal is transmitted to a camera control unit (CCU) 1135 as RAW data.

The CCU 1135 includes a central processing unit (CPU) and a graphics processing unit (GPU), and comprehensively controls operations of the endoscope 1100 and a display device 1136. Further, the CCU 1135 receives an image signal from the camera head 1102 and performs various types of image processing for displaying an image based on the image signal, such as a development process (demosaic process), on the image signal.

Based on the control of the CCU 1135, the display device 1136 displays an image based on the image signal subjected to the image processing performed by the CCU 1135.

The light source device 1203 includes a light source, such as a light-emitting diode (LED), and supplies emission light for image capturing of an operation site to the endoscope 1100.

An input device 1137 is an input interface for an input to the endoscopic operation system 1150. A user can input various pieces of information and input an instruction to the endoscopic operation system 1150 via the input device 1137.

A treatment tool control device 1138 controls driving of energy treatment tools 1112 for cauterizing or incising tissue or sealing blood vessels.

The light source device 1203 that supplies emission light for capturing an operation site to the endoscope 1100 can include an LED, a laser light source, or a white light source configured by the combination of these, for example. In a case of a white light source including a combination of RGB laser light sources, the output intensity and an output timing of each color (each wavelength) can be controlled highly accuracy, and thus the white balance of a captured image can be adjusted in the light source device 1203. In this case, laser light is emitted from each of the RGB laser light sources onto the observation target in a time division manner, and the driving of an imaging element of the camera head 1102 is controlled in synchronization with the emission timing of the laser light, whereby an image corresponding to each of RGB can also be captured in a time division manner. According to this method, it is possible to obtain a color image without providing color filters in the imaging element.

The driving of the light source device 1203 may be controlled in such a manner that the intensity of light to be output from the light source device 1203 is changed every predetermined time. Images are acquired in a time division manner by controlling the driving of the image element of the camera head 1102 in synchronization with the change timing of the light intensity, and the images are combined, whereby a high dynamic range image without so-called blocked-up shadows and blown-out highlights is generated.

The light source device 1203 may also be configured to supply light in a predetermined wavelength band adapted to special light observation. In the special light observation, for example, the wavelength dependence of light absorption of body tissues is utilized. Specifically, light in a narrower band than emission light (i.e., white light) in normal observation is emitted to capture an image of a predetermined tissue, such as blood vessels in a superficial layer of a mucous membrane, with high contrast.

Alternatively, in the special light observation, fluorescence observation to obtain an image with fluorescent light generated by emitting excitation light may be performed. In the fluorescence observation, fluorescent light from the tissue of the body is observed by emitting excitation light onto the body tissue, or a fluorescent image is obtained by locally injecting reagent, such as indocyanine green (ICG), into a body tissue and emitting excitation light suitable for a fluorescence wavelength of the reagent onto the body tissue. The light source device 1203 can be configured to supply narrow-band light and/or excitation light adapted to such special light observation.

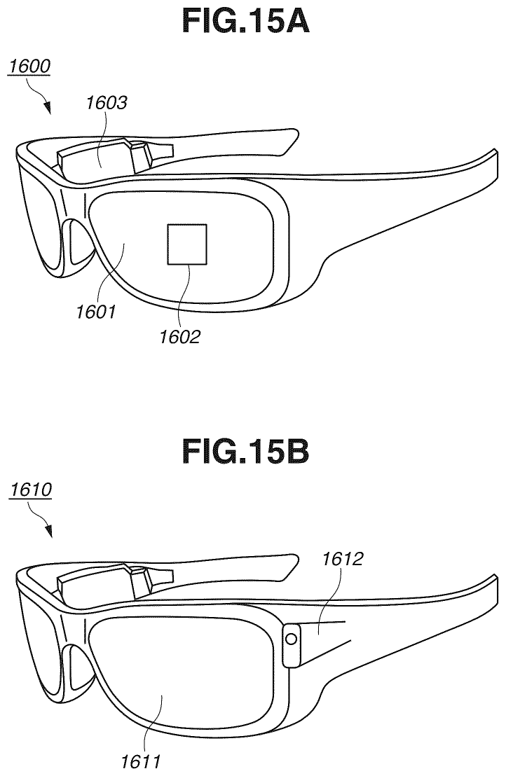

With reference to FIGS. 15A and 15B, a photoelectric conversion system according to a tenth exemplary embodiment is described. FIG. 15A illustrates eyeglasses 1600 (smart glasses) that are the photoelectric conversion system according to the present exemplary embodiment. The eyeglasses 1600 include a photoelectric conversion apparatus 1602. The photoelectric conversion apparatus 1602 is the photoelectric conversion apparatus (imaging apparatus) described in any of the above-described exemplary embodiments. On the back surface side of a lens 1601, a display device including a light emission device, such as an organic light emitting diode (OLED) or an LED, may be disposed. The number of photoelectric conversion apparatuses 1602 may be one or plural. In addition, a plurality of types of photoelectric conversion apparatuses 1602 may be used in combination. An arrangement position of the photoelectric conversion apparatus 1602 is not limited to the position illustrated in FIG. 15A.

The eyeglasses 1600 further include a control device 1603. The control device 1603 functions as a power source that supplies power to the photoelectric conversion apparatus 1602 and the above-described display device. The control device 1603 also controls operations of the photoelectric conversion apparatus 1602 and the display device. In the lens 1601, an optical system for condensing light to the photoelectric conversion apparatus 1602 is formed.

FIG. 15B illustrates eyeglasses 1610 (smart glasses) as an application example. The eyeglasses 1610 include a control device 1612, and the control device 1612 is equipped with a photoelectric conversion apparatus equivalent to the photoelectric conversion apparatus 1602, and a display device. In a lens 1611, an optical system for projecting light emitted from the photoelectric conversion apparatus and the display device in the control device 1612 is formed, and an image is projected onto the lens 1611. The control device 1612 functions as a power source that supplies power to the photoelectric conversion apparatus and the display device and controls operations of the photoelectric conversion apparatus and the display device. The control device 1612 may include a line of sight detection unit that detects a line of sight of a wearer (user). Infrared light may be used for the detection of a line of sight. An infrared light emission unit emits infrared light onto an eyeball of a user looking at a displayed image. An imaging unit including a light receiving element detects reflected light of the emitted infrared light that has been reflected from the eyeball, whereby a captured image of the eyeball is obtained. A reduction unit for reducing light from the infrared light emission unit to a display unit in a planar view is disposed so that a decline in image quality is suppressed.

A captured image of an eyeball obtained by the image capturing using infrared light is used to detect a line of sight of the user with respect to a displayed image. Any known method can be applied to the line of sight detection using a captured image of an eyeball. As an example, a line of sight detection method based on a Purkinje image obtained by reflection of irradiating light on a cornea can be used.

More specifically, a line of sight detection process based on the pupil center corneal reflection method is performed. A line of sight vector representing the direction (rotational angle) of an eyeball is calculated using the pupil center corneal reflection method, based on an image of a pupil and a Purkinje image that are included in a captured image of the eyeball, whereby a line of sight of the user is detected.

The display device of the present exemplary embodiment may include the photoelectric conversion apparatus including a light receiving element, and a displayed image on the display device may be controlled based on line of sight information on the user from the photoelectric conversion apparatus.

Specifically, in the display device, a first field of view region viewed by the user, and a second field of view region other than the first field of view region are determined based on the line of sight information. The first field of view region and the second field of view region may be determined by a control device of the display device, or the display device may receive the first field of view region and the second field of view region determined by an external control apparatus. In a display region of the display device, a display resolution of the first field of view region may be controlled to be higher than a display resolution of the second field of view region. More specifically, a resolution of the second field of view region may be set lower than a resolution of the first field of view region.

In addition, the display region includes a first display region and a second display region different from the first display region. Based on the line of sight information, a region with high priority may be determined from the first display region and the second display region. The first display region and the second display region may be determined by the control device of the display device, or the display device may receive the first display region and the second display region determined by an external control apparatus. Control may be performed in such a manner that a resolution of a region with high priority is controlled to be higher than a resolution of a region other than the region with high priority. In other words, a resolution of a region with relatively-low priority may be set to a low resolution.

Artificial intelligence (AI) may be used for determination of the first field of view region and the region with high priority. The AI may be a model configured to estimate an angle of a line of sight and a distance to a target object existing at the end of the line of sight, from an image of an eyeball by using training data including an image of the eyeball and a direction in which the eyeball in the image actually gives a gaze. An AI program may be included in the display device, the photoelectric conversion apparatus, or an external apparatus. In a case where an external apparatus includes an AI program, the AI program is transmitted to the display device via communication.

In a case where display control is performed based on line of sight detection, the aspect of the embodiments can be suitably applied to smart glasses further including a photoelectric conversion apparatus that captures an image of the outside. The smart glasses can display external information obtained by image capturing, in real time.

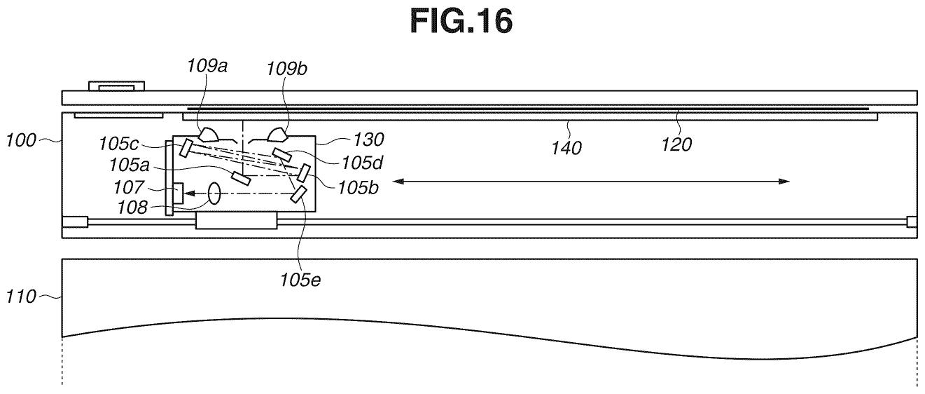

FIG. 16 is a cross-sectional view illustrating an internal configuration of a document reading apparatus 100 serving as an image reading apparatus. An image forming unit 110 which is a known image forming unit is disposed under the document reading apparatus 100. The document reading apparatus 100 and the image forming unit 110 serve together as an image forming apparatus. An electrophotographic image forming unit is an example of the known image forming unit. In image formation, the image forming unit 110 of an electrophotographic type develops an electrostatic latent image formed on a photosensitive drum into a toner image, and transfers the toner image to a recording medium, such as paper. The image forming apparatus according to an eleventh exemplary embodiment forms an image read by the document reading apparatus 100 on a recording medium by using the image forming unit 110.

A sheet (hereinafter referred to as a document) 120 with an image as a reading target formed thereon is placed on a document platen 140. In response to the user pressing a reading start button (not illustrated), a reading unit 130 moves in the direction of the arrow and reads the document 120.

In moving in the direction of the arrow, the reading unit 130 turns ON white Light Emitting Diodes (LEDs) 109a and 109b as light emission units disposed on the top side of the reading unit 130 to irradiate the document 120 with light.

The reading unit 130, which is a reduction optical system, includes the LEDs 109a and 109b, a plurality of reflective mirrors 105a, 105b, 105c, 105d, and 105e, a condensing lens 108, and a photoelectric conversion apparatus 107. The light radiated to the document 120 by the LEDs 109a and 109b is reflected by the document 120. The light reflected by the document 120 is reflected by the reflective mirrors 105a, 105b, 105c, 105d, and 105e and then condensed to the photoelectric conversion apparatus 107 serving as a line sensor by the condensing lens 108. The photoelectric conversion apparatus 107 includes a light receiving element that performs photoelectric conversion on the incident light and outputs an electrical signal corresponding to the amount of incident light.

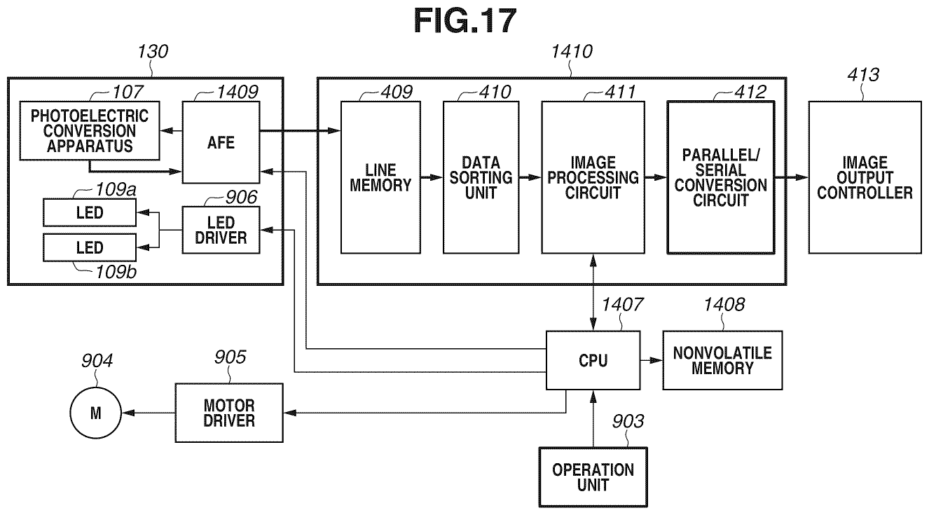

FIG. 17 is a block diagram illustrating the document reading apparatus 100 according to the present exemplary embodiment.

A CPU 1407 reads a control program stored in a nonvolatile memory 1408 and executes the program to control the entire operation of the document reading apparatus 100. An operation unit 903 is a user interface via which the user sets a copy mode (color copy, monochrome copy, and double-sided copy) and inputs a copy start instruction. A motor 904 moves the reading unit 130 in the sub scanning direction. A motor driver 905 receives a timing signal from the CPU 1407 and supplies an excitation current for control of the rotation of the motor 904.

A LED driver 906 receives a timing signal from the CPU 1407 and supplies a current for turning ON the while LEDs 109a and 109b.

An integrated circuit (IC) 1409 performs sampling and holding processing, offset processing, gain processing, and other analog processing on an analog voltage signal output from the photoelectric conversion apparatus 107, and converts the voltage signal obtained by the analog processing into digital data (hereinafter referred to as luminance data). The IC 1409 is generally referred to as an Analog Front End (AFE). According to the present exemplary embodiment, this digital data is 8-bit (0 to 255) data.

The operation of an image processing unit 1410 will be described below. Readout data output from the AFE 407 is stored in a line memory 409. The line memory 409 stores readout data read by light receiving element lines 1, 2, and 3 in the photoelectric conversion apparatus 107.

A data sorting unit 410 sorts the readout data acquired by the lines 1, 2, and 3 and generates image data of different colors (red, green, and blue [RGB]). For example, processing of R will be described below. The data sorting unit 410 picks up an R data portion from the image data of the lines 1, 2, and 3 stored in the line memory 409. Because the readout data of the lines 1, 2, and 3 acquired at a certain timing is deviated in the sub scanning direction, the photoelectric conversion apparatus 101 performs processing to cancel the deviation. More specifically, the photoelectric conversion apparatus 101 performs processing on data acquired at a certain timing to shift the readout data of the line 2 by 2 pixels in the sub scanning direction and shift the readout data of the line 3 by 4 pixels in the sub scanning direction. This processing cancels the deviation in the sub scanning direction. This processing for each color cancels the deviation of the readout data (read by the photoelectric conversion apparatus 107) in the sub scanning direction, whereby readout data corresponding to the image of the document 120 is acquired.

An image processing circuit 411 performs shading correction processing and filtering processing on the readout data sorted by the data sorting unit 410. Filter and other settings to be used for the image processing are set in registers in the image processing circuit 411 by the CPU 1407 when the power is turned ON.

A parallel/serial conversion circuit 412 converts the readout data (parallel data) obtained by various image processing output from the image processing circuit 411 into serial data. The readout data converted to serial data is sent to an image output controller 413.

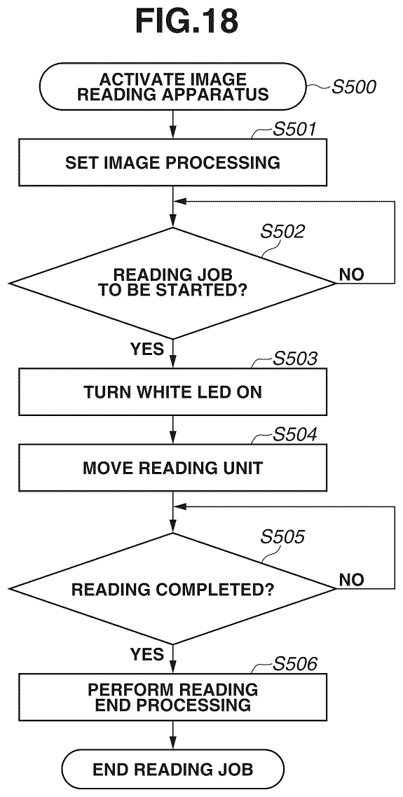

FIG. 18 is a flowchart illustrating control by the CPU 1407 according to the present exemplary embodiment.

When the user turns ON the power of the document reading apparatus 100, then in step S500, the CPU 1407 starts a document reading apparatus control program and performs initial operations, such as light quantity adjustment for LED light sources (activation of the document reading apparatus 100).

In step S501, the CPU 1407 sets data corresponding to image processing settings to registers in the image processing circuit 411.

In step S502, the CPU 1407 waits for a reading job start instruction from the operation unit 903.

When the user inputs the reading job start instruction (YES in step S502), the processing proceeds to step S503. In step S503, the CPU 1407 turns ON the white LEDs 109a and 109b serving as light sources. The CPU 1407 outputs a control signal to the LED driver 906, and the LED driver 906 supplies a current to the LEDs 109a and 109b for light emission.

In step S504, the CPU 1407 outputs a control signal to the motor driver 905, and the motor driver 905 drives the motor 904 to move the reading unit 130 in the sub scanning direction.

In a case where the reading operation is completed (YES in step S505), the processing proceeds to step S506. In step S506, the CPU 1407 turns OFF the LEDs 109a and 109b and controls the document reading apparatus 100 to enter a job waiting state.

In this specification, expressions such as “A or B”, “at least one of A and B”, “at least one of A and/or B”, and “one or more of A and/or B” may be used. This case may include all possible combinations of the listed items, unless explicitly defined otherwise.

That is, the above expression is understood to disclose all cases of including at least one A, including at least one B, and including both at least one A and at least one B. This applies equally to combinations of three or more elements.

The disclosure herein includes the complement of the concepts described herein. That is, for example, when the description “A is B” (A=B) is present in the present specification, even if the description “A is not B” (A+B) is omitted, the present specification discloses or suggests that “A is not B”. This is because, the description “A is B” is described, based on the premise that the case “A is not B” is considered.

The exemplary embodiments described above can be appropriately modified without departing from the technical idea. The disclosure of the present specification includes not only the matters described in the present specification but also all matters that can be grasped from the present specification and the drawings attached to the present specification. That is, even if the description “A is not larger than B” is omitted when the description “A is larger than B” is given in the present specification, the present specification can be said to disclose “A is not larger than B”. This is because the description “A is larger than B” is based on the premise that the case “A is not larger than B” is considered.

The aspect of the embodiments enables further reducing a parasitic capacitance that occurs in a floating diffusion, whereby crosstalk is prevented.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-202722, filed Nov. 30, 2023, which is hereby incorporated by reference herein in its entirety.

What is claimed is:

1. A apparatus comprising:
a plurality of pixels each including a photoelectric conversion unit, a floating diffusion unit, an amplifying transistor that has a gate and is configured to amplify a signal based on the floating diffusion unit and output the signal as a pixel signal, and a selection transistor configured to control output of the amplified pixel signal;
a shield wiring disposed to cover at least a part of the gate in a planar view viewed from a direction perpendicularly intersecting with a surface where the plurality of pixels is disposed;
a first diffusion region configured to serve as a source or drain of the amplifying transistor;
a second diffusion region configured to serve as a source or drain of the selection transistor;
at least one first contact connected to the first diffusion region; and
at least one second contact connected to the second diffusion region,
wherein the gate, the first diffusion region, and the second diffusion region are adjacently disposed on a straight line in a first direction, and
wherein, in a second direction perpendicularly intersecting with the first direction, a sum of widths of the at least one first contact is longer than a sum of widths of the at least one second contact.

2. An apparatus comprising:
a plurality of pixels each including a photoelectric conversion unit, a floating diffusion unit, an amplifying transistor that has a gate and is configured to amplify a signal based on the floating diffusion unit and output the signal as a pixel signal, a selection transistor configured to control output of the pixel signal amplified by the amplifying transistor, and a wiring mainly made of copper;
a first diffusion region configured to serve as a source or drain of the amplifying transistor;
a second diffusion region configured to serve as the source or drain of the selection transistor;
at least one first contact connected to the first diffusion region and the wiring; and
at least one second contact connected to the second diffusion region,
wherein the gate, the first diffusion region, and the second diffusion region are adjacently disposed on a straight line in a first direction, and
wherein, in a second direction perpendicularly intersecting with the first direction, a sum of widths of the at least one first contact is longer than a sum of widths of the at least one second contact.

3. The apparatus according to claim 1,
wherein the at least one first contact includes one first contact,
wherein the at least one second contact includes one second contact, and
wherein, in the second direction, a width of the one first contact is longer than a width of the second contact.

4. The apparatus according to claim 3, wherein a width of the first contact in the second direction is longer than a length of the first contact in the first direction.

5. The apparatus according to claim 2,
wherein the at least one first contact includes one first contact,
wherein the at least one second contact includes one second contact, and
wherein, in the second direction, a width of the one first contact is longer than a width of the second contact.

6. The apparatus according to claim 5, wherein a width of the first contact in the second direction is longer than a length of the first contact in the first direction.

7. The apparatus according to claim 1, wherein the number of first contacts is more than the number of second contacts.

8. The apparatus according to claim 2, wherein the number of first contacts is more than the number of second contacts.

9. The apparatus according to claim 7, wherein at least two first contacts are disposed on a straight line in the second direction.

10. The apparatus according to claim 8, wherein at least two first contacts are disposed on a straight line in the second direction.

11. The apparatus according to claim 1,
wherein the selection transistor has a gate, and
wherein a gate width of the amplifying transistor is longer than a gate width of the selection transistor.

12. The apparatus according to claim 2,
wherein the selection transistor has a gate, and
wherein a gate width of the amplifying transistor is longer than a gate width of the selection transistor.

13. The apparatus according to claim 1,
wherein each of the plurality of pixels includes a plurality of the selection transistors, and
wherein drains of the plurality of the selection transistors are connected to an output of the amplifying transistor.

14. The apparatus according to claim 2,
wherein each of the plurality of pixels includes a plurality of the selection transistors, and
wherein drains of the plurality of the selection transistors are connected to an output of the amplifying transistor.

15. The apparatus according to claim 1,
wherein the plurality of pixels is arranged in a plurality of rows and a plurality of columns,
wherein at least two signal lines are disposed for one of the plurality of columns, and
wherein the at least two signal lines are disposed in a wiring layer different from the shield wiring.

16. The apparatus according to claim 15, wherein the gate of the amplifying transistor, the shield wiring, and the at least two signal lines are overlapped in a planar view viewed from the direction perpendicularly intersecting with the surface where the plurality of pixels is disposed.

17. The apparatus according to claim 1,
wherein the photoelectric conversion unit is disposed in a semiconductor layer, and
wherein, in the semiconductor layer, light is radiated from a side opposite to a side where the first contact is connected.

18. The apparatus according to claim 1,
wherein the conversion unit is disposed in a first semiconductor layer,
wherein a scanning circuit for controlling driving of the plurality of pixels is disposed in a second semiconductor layer, and
wherein the first semiconductor layer and the second semiconductor layer are stacked.

19. The apparatus according to claim 1, wherein an element isolation region is disposed between the first diffusion region and the second diffusion region.

20. The apparatus according to claim 2,
wherein the photoelectric conversion unit is disposed in a semiconductor layer, and
wherein, in the semiconductor layer, light is radiated from a side opposite to a side where the first contact is connected.

21. The apparatus according to claim 2,
wherein the photoelectric conversion unit is disposed in a first semiconductor layer,
wherein a scanning circuit for controlling driving of the plurality of pixels is disposed in a second semiconductor layer, and
wherein the first semiconductor layer and the second semiconductor layer are stacked.

22. The apparatus according to claim 2, wherein an element isolation region is disposed between the first diffusion region and the second diffusion region.

23. A system comprising:
the apparatus according to claim 1; and
a processing unit configured to generate an image by using a signal output from the apparatus.

24. A moving object comprising:
the apparatus according to claim 1; and
a control unit configured to control a movement of the moving object by using a signal output from the apparatus.
